(19) United States
(12) Patent Application Publication
(10) Pub. No.: US 2014/0021335 A1
(43) Pub. Date: Jan. 23, 2014

(54) MICROPROCESSOR BASED MULTI-JUNCTION DETECTOR SYSTEM AND METHOD OF USE

(71) Applicants: Razvan Ciocan, Auburndale, MA (US); Domenic Assalone, Milford, CT (US); John Donohue, Shelton, CT (US); Dae Han, Trumbull, CT (US); Zhuoyun Li, N.Grafion, MA (US)

(72) Inventors: Razvan Ciocan, Auburndale, MA (US); Domenic Assalone, Milford, CT (US); John Donohue, Shelton, CT (US); Dae Han, Trumbull, CT (US); Zhuoyun Li, N.Grafion, MA (US)

(73) Assignee: NEWPORT CORPORATION, Irvine, CA (US)

(21) Appl. No.: 13/819,695

(22) PCT Filed: Aug. 31, 2011
(86) PCT No.: PCT/US2011/050022

§ 371 Date: Sep. 25, 2013

Related U.S. Application Data
(60) Provisional application No. 61/380,249, filed on Sep. 5, 2010.

(51) Int. Cl. H01L 31/09

(52) U.S. Cl. CPC H01L 31/09
USPC 250/214 A; 250/206; 250/214 DC

(57) ABSTRACT

The disclosure relates to a photodetector system including a multi-junction detector having a first junction configured to generate a first current when irradiated with a first optical radiation component within a first spectral range, and at least a second junction configured to generate a second current when irradiated with a second optical radiation component within a second spectral range that is different than the first spectral range. The photodetector system also comprises a microprocessor adapted to generate a first indication related to a first characteristic of the first optical radiation component based on the first current, and generate a second indication related to a second characteristic of the second optical radiation component based on the second current.

### CROSS-REFERENCE TO A RELATED APPLICATION

This application is the National Stage of International Application No. PCT/US2011/050022, filed on Aug. 31, 2011, which claims the benefit under 35 U.S.C. §119(e) of U.S. Provisional Application Ser. No. 61/380,249, filed on Sep. 5, 2010, both of which are incorporated herein by reference.

### FIELD

This disclosure relates generally to photo or optical detection, and in particular, to a microprocessor based multi-junction detector system and method of use.

### BACKGROUND

Photodiodes are the most commonly used photodetectors in use today. Presently, they are used in any variety of applications and are being incorporated into numerous additional applications. Generally, photodiodes offer a compact, rugged, low cost alternative to photomultipliers.

Currently, photodiodes are manufactured from a number of distinct materials, each material offering sensitivity within a defined range of the electromagnetic spectrum. For example, Silicon-based photodiodes typically produce significant photocurrents when irradiated with a signal having a wavelength from about 180 nm to about 1100 nm. In contrast, Germanium-based photodiodes produce significant photocurrents when irradiated with a signal having a wavelength from about 400 nm to about 1700 nm. Similarly, Indium Gallium Arsenide-based photodiodes are commonly used to detect signals having a wavelength from about 800 nm to about 2600 nm, while Lead Sulfide-based photodiodes are used to detect signals having a wavelength of about 1000 nm to about 3500 nm.

Further, the responsivity of these devices varies depending on the wavelength of the incident signal. For example, while Silicon-based photodetectors are capable of detecting signal having a wavelength from about 180 nm to 1100 nm, the highest responsivity is from about 850 nm to about 1000 nm. As such, the measurement of broad spectral ranges typically requires multiple photodetectors, each using photodiodes manufactured from different materials. As such, systems incorporating multiple photodetectors manufactured from various materials may be quite large and unnecessarily complex.

Thus, there is an ongoing need for microprocessor based multi-junction detector system capable of detecting an incident signal with high responsivity at a variety of wavelengths.

### SUMMARY

An aspect of the disclosure relates to a photodetector system, comprising a multi-junction photodetector device comprising a first junction configured to generate a first current when irradiated with a first optical radiation component within a first spectral range, and at least a second junction configured to generate a second current when irradiated with a second optical radiation component within a second spectral range that is different than the first spectral range. The photodetector system also comprises a microprocessor adapted to generate a first indication related to a first characteristic of the first optical radiation component based on the first current, and generate a second indication related to a second characteristic of the second optical radiation component based on the second current.

In another aspect of the disclosure, the first characteristic of the first optical radiation component comprises a first power level of the first optical radiation component, and the second characteristic of the second optical radiation component comprises a second power level of the second optical radiation component. In yet another aspect, the photodetector system comprises a first device (e.g., a transimpedance amplifier, charge amplifier, etc.) adapted to generate a first analog voltage based on the first current, and at least a second device (e.g., a transimpedance amplifier, charge amplifier, etc.) adapted to generate a second analog voltage based on the second current.

In another aspect of the disclosure, the microprocessor is adapted to control a first gain of the first transimpedance amplifier, and control a second gain of the second transimpedance amplifier. In still another aspect, the microprocessor is adapted to control the first gain of the first transimpedance amplifier in order to minimize compression of the first transimpedance amplifier at a first defined high power level of the first optical radiation component, and control the second gain of the second transimpedance amplifier in order to minimize compression of the second transimpedance amplifier at a second defined high power level of the second optical radiation component. In yet another aspect, the microprocessor is adapted to control the first gain of the first transimpedance amplifier in order to achieve a first defined sensitivity for the first transimpedance amplifier at a first defined low power level of the first optical radiation component, and control the second gain of the second transimpedance amplifier in order to achieve a second defined sensitivity for the second transimpedance amplifier at a second defined low power level of the second optical radiation component.

In another aspect of the disclosure, the photodetector system further comprises an analog-to-digital converter adapted to convert the first analog voltage into a first digital voltage, and convert the second analog voltage into a second digital voltage. In yet another aspect, the photodetector system further comprises a multiplexer adapted to multiplex the first and second digital voltages onto an output, wherein the microprocessor is adapted to receive the first and second digital voltages from the output of the multiplexer.

In another aspect of the disclosure, the photodetector system further comprises a communication device adapted to facilitate communication of information between the microprocessor and one or more external devices. In still another aspect, the microprocessor is adapted to provide data related to the first and second power level indications to the one or more external devices by way of the communication device. In yet another aspect, the communication device comprises a Universal Serial Bus (USB) port. In still another aspect, the communication device comprises a wireless communication device.

In another aspect of the disclosure, the photodetector system comprises an analog interface connector adapted to output the first and second analog voltages for transmission to one or more external devices. In yet another aspect, the microprocessor is adapted to enable or disable the outputting of the first and second analog voltages via the analog interface connector. In still another aspect, the photodetector system comprises a digital interface connector adapted to output the first and second digital voltages for transmission to one or more external devices. In an additional aspect, the microprocessor is adapted to enable or disable the outputting of the first and second digital voltages via the digital interface connector.

In another aspect of the disclosure, the photodetector system comprises a memory including one or more software modules readable and executable by the microprocessor to perform its various operations as described herein. In still another aspect, the memory further comprises data related to the first and second indications of the first and second power levels of the first and second optical radiation component, respectively. In yet another aspect, the photodetector system comprises a housing to enclose any one or more of the various components of the system, including the multi-junction photodetector device, transimpedance amplifiers, analog-to-digital converter, multiplexer, microprocessor, memory, and external device interface(s). In an additional aspect, the housing includes an aperture through which optical radiation is received by the photodetector system.

Other aspects, advantages and novel features of the disclosure will become apparent from the following detailed description of the invention when considered in conjunction with the accompanying drawings.

### BRIEF DESCRIPTION OF THE DRAWINGS

FIG. 1 illustrates a front perspective view of an exemplary microprocessor-based, multi-junction photodetector unit in accordance with an aspect of the disclosure.

FIG. 2 illustrates a rear perspective view of an exemplary microprocessor-based, multi-junction photodetector unit in accordance with another aspect of the disclosure.

FIG. 3 illustrates a block diagram of an exemplary microprocessor-based, multi-junction photodetector system in accordance with another aspect of the disclosure.

FIG. 4 illustrates a block diagram of another exemplary microprocessor-based, multi-junction photodetector system in accordance with another aspect of the disclosure.

FIG. 5 illustrates a flow diagram of an exemplary method of calibrating respective gains of transimpedance amplifiers associated with an exemplary microprocessor-based, multi-junction photodetector system in accordance with another aspect of the disclosure.

FIG. 6 illustrates a flow diagram of an exemplary method of determining or calibrating a power-to-voltage response associated with an exemplary microprocessor-based, multi-junction photodetector system in accordance with another aspect of the disclosure.

FIG. 7 shows graphically a test result of a performance of an exemplary Si-junction and Ge-junction photodetector system as described herein when illuminated with a Quartz halogen lamp.

FIG. 8 shows graphically a test result of a performance of an exemplary Si-junction and InGaAs-junction photodetector system as described herein when illuminated with a Quartz halogen lamp.

### DETAILED DESCRIPTION OF THE EXEMPLARY EMBODIMENTS

FIGS. 1-3 show various views of an embodiment of a microprocessor based multi-junction detector system 10. As shown, the detector system 10 includes a housing 12 configured to protectively contain the various components of the detector therein. In one embodiment, the housing 12 is constructed of aluminum. Optionally, any variety of materials may be used to form the housing 12, including, without limitations, aluminum, steel, alloys, polymers, composite materials, and the like. In addition, the housing 12 may be formed in any variety of shapes, sizes, and configurations.

Referring again to FIGS. 1-3, the housing 12 may contain any variety of electronic systems or devices therein. In the illustrated embodiment, the housing 12 includes at least one multi-junction photodetector 14 therein. More specifically, the photodetector 14 includes a first junction configured to generate a first photocurrent when irradiated with optical radiation within a first spectral range and at least a second junction configured to generate a second photocurrent when irradiated with optical radiation within at least a second spectral range. In one embodiment, the photodetector 14 comprises a Silicon-based junction and a Germanium-based junction. In another embodiment, numerous multi-junction photodetectors 14 are positioned within the housing 12. Optionally, the photodetector 14 may include any number and/or type of materials to form the multi-junction semiconductor. As such, unlike the narrow range of operation of prior art single junction devices, the multi-junction photodetector 14 disclosed herein permits an expanded range of operation with a single device. The photodetector 14 may be positioned proximate to at least one window or aperture 32 formed in the housing 14.

As shown in FIGS. 1-3, at least one transimpedence amplifier may be coupled to or otherwise in electrical communication with the photodetector 14. In the illustrated embodiment, a first amplifier 15 is configured to receive the first photocurrent generated by a junction of the multi-junction photodetector 14 and generate a first amplified voltage J₁ therefrom. Similarly, at least a second amplifier 18 is configured to receive at least the second photocurrent generated by another junction of the multi-junction photodetector 14 and generate at least a second amplified voltage J_{N} therefrom. For example, the first amplifier 15 may be configured to receive photocurrent from the Silicon-based portion of the photodetector 14, while the second amplifier 18 is configured to receive photocurrent from the Germanium-based portion of the photodetector 14.

Referring again to FIGS. 1-3, at least one analog-to-digital converter 20 (hereinafter A/D converter) is in communication with the first and second amplifiers 15, 18. The A/D converter 20 is configured to receive the analog output from the amplifiers 15, 18 and generate a digital output in response thereto. Any number and/or type of A/D converters 20 may be used with the present system. The digital output of the A/D converter 20 is processed by at least one microprocessor 22 located within the housing 12. The microprocessor 22 may be configured to store any variety of information, device characteristics, device history, algorithms, formulas, data libraries, and the like within at least one memory device 24 coupled thereto. For example, the microprocessor 22 may be configured to control the gain of the first and second amplifiers 15, 18, permit calibration of the photodetector 14, calculate the optical power measured by the photodetector 14, store measured data and/or device characteristics, and regulate communication between the multi-junction photodetector system 10 and external devices (not shown) such as computers and the like.

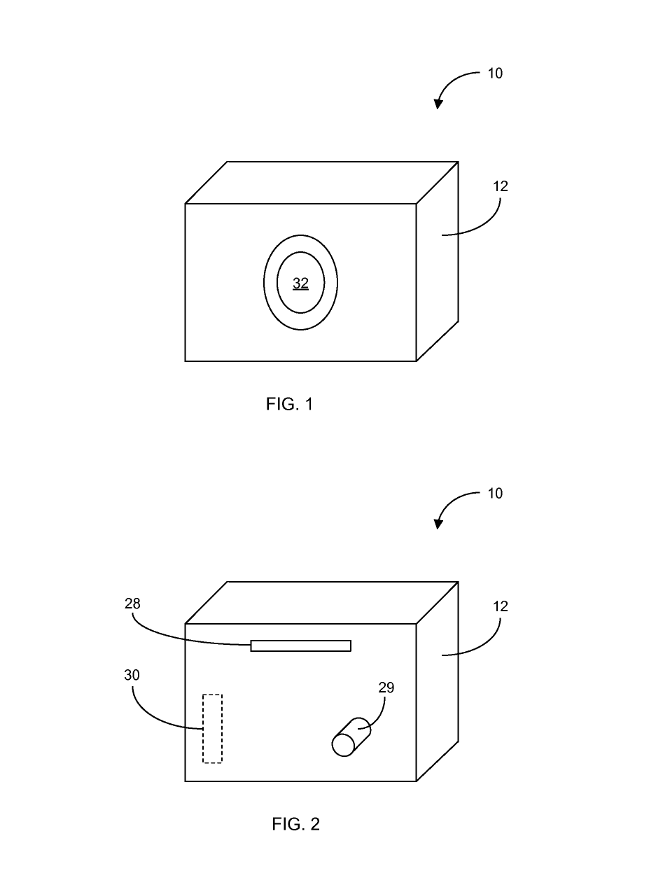

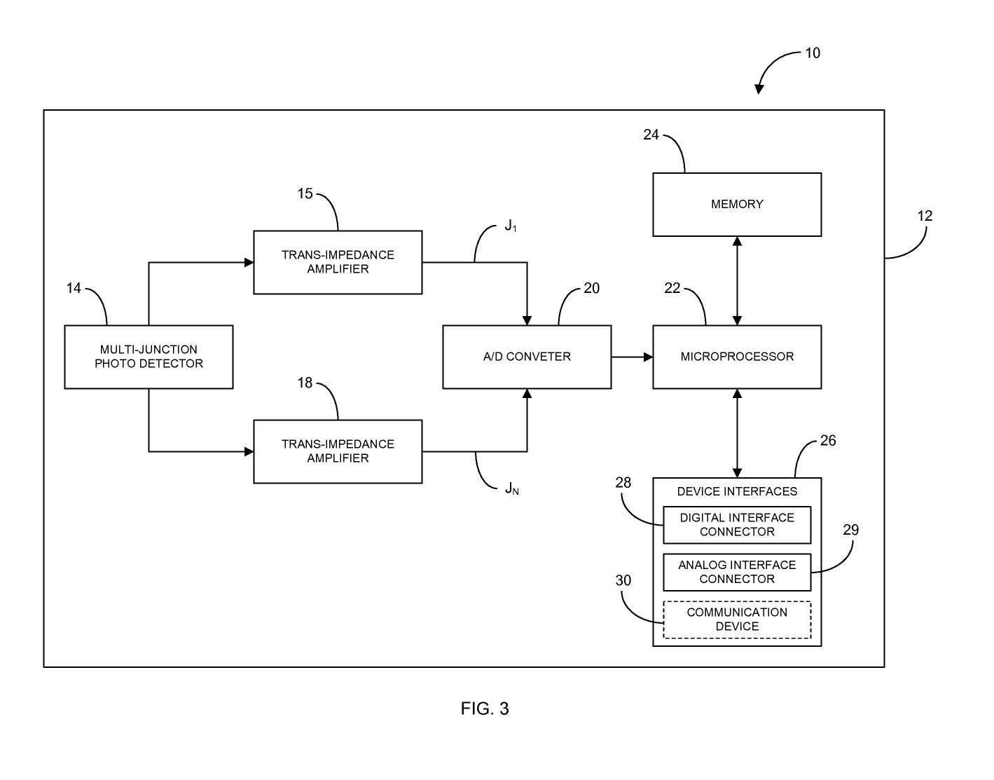

As shown in FIGS. 1-3, the detector system 10 may further include any number of device interfaces 26 thereby enabling the detector system 10 to be coupled to or otherwise communicate with one or more external devices (not shown). For example, as shown in FIGS. 2 and 3, at least one digital interface connector 28 may be positioned on or proximate to the housing 12 thereby permitting the detector device 10 to be coupled to an external device (e.g., a computer) via at least one data cable. Exemplary digital interface connectors 28 include USB ports, cable ports, and the like. Alternatively, or in addition to, the device interface 26 may include an analog interface connector 29 adapted to output the analog voltages J₁ to J_{N} from the corresponding transimpedance amplifiers 15 and 18. Optionally, the device interface 26 may include a wireless communication device 30, such as a WiFi antenna or similar device, thereby permitting the photodetector system 10 to wirelessly communicate with an external device (not shown).

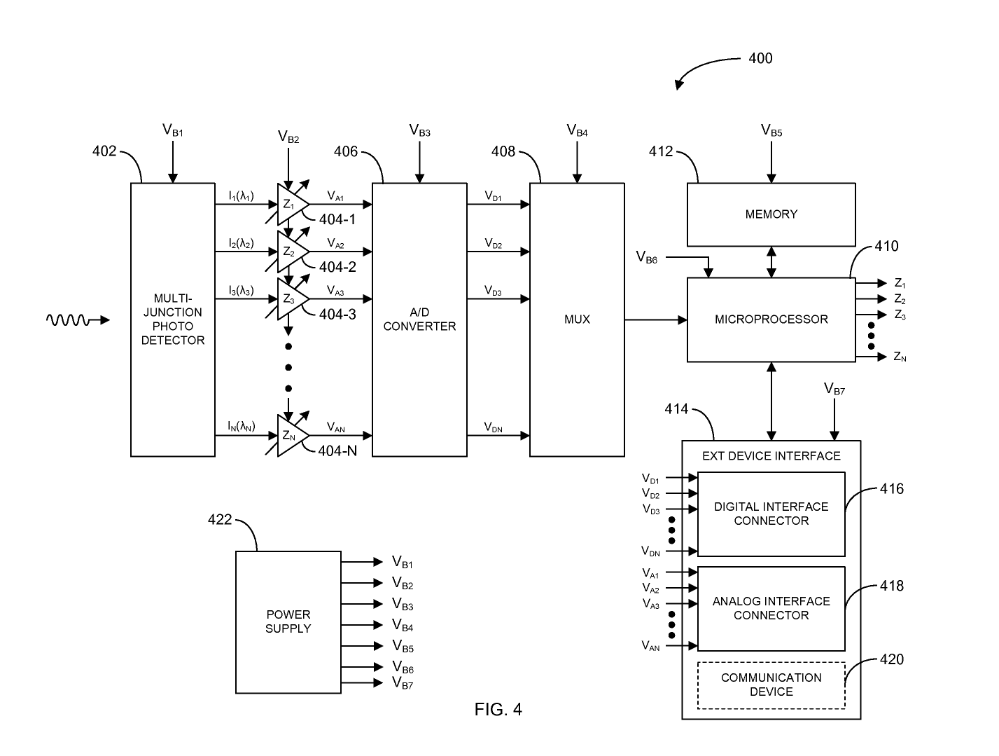

FIG. 4 illustrates a block diagram of another exemplary microprocessor-based, multi-junction photodetector system 400 in accordance with another aspect of the disclosure. The photodetector system 400 comprises a multi-junction photodetector 402, which may be configured as a single device (e.g., a semiconductor chip or die, an organic polymer, etc.) having two or more junctions adapted to detect signals at distinct wavelengths or frequency bands, respectively. For instance, in this example, the multi-junction photo detector includes N distinct junctions, where N is two or more. For example, the distinct junctions of the multi-junction photodetector 402 may generate currents I₁, I₂, I₃ to I_{N} when irradiated with electromagnetic energy signals of distinct wavelengths or spectral ranges λ₁, λ₂, λ₃ to λ_{N}, respectively. Thus, the generated currents I₁, I₂, I₃ to I_{N} are function of the wavelengths λ₁, λ₂, λ₃ to λ_{N} of the signals irradiating the photodetector 402, respectively.

The photodetector system 400 further comprises a plurality of transimpedance amplifiers 404-1 to 404-N, where N is two or more. In this example, the plurality of transimpedance amplifiers 402-1, 402-2, 402-3 to 404-N are adapted to convert the currents I₁(λ₁), I₂(λ₂), I₃(λ₃) to I_{N}(λ_{N}) generated by the distinct junctions of the photodetector 402 into analog voltages V_{A1}, V_{A2}, V_{A3} to V_{AN}, respectively. The plurality of transimpedance amplifiers 402-1, 402-2, 402-3 to 404-N may have associated gains Z₁, Z₂, Z₃ to Z_{N} for converting the currents I₁(λ₁), I₂(λ₂), I₃(λ₃) to I_{N}(λ_{N}) into the analog voltages V_{A1}, V_{A2}, V_{A3} to V_{AN}, respectively.

The photodetector system 400 further comprises an analog-to-digital (A/D) converter 408 adapted to convert the analog voltages V_{A1}, V_{A2}, V_{A3} to V_{AN} from the outputs of the transimpedance amplifiers 404-1, 404-2, 404-3 to 404-N into digital voltages V_{D1}, V_{D2}, V_{D3} to V_{DN}, respectively. Additionally, the photodetector system 400 includes a multiplexer 408 for multiplexing the digital voltages V_{D1}, V_{D2}, V_{D3} to V_{DN} onto a single output. The output of the multiplexer 408 is coupled to an input of a microprocessor 410.

Similar to the previous embodiment, the microprocessor 410 may be configured to store any variety of information, device characteristics, device history, algorithms, formulas, data libraries, and the like within at least one memory device 412 coupled thereto. For example, the microprocessor 400 may be configured to control the respective gains Z₁ to Z_{N} of the transimpedance amplifiers 404-1 to 404-N, permit calibration of the photodetector 402, calculate the optical power measured by the photodetector 402, store measured data and/or device characteristics, and regulate communication between the photodetector system 400 and external devices. The photodetector system 400 also includes a memory 412 associated with the microprocessor 410 and adapted to store one or more software modules, data, and other parameters in accordance with the functionality of the photodetector system described herein.

Also, similar to the previous embodiment, the photodetector system 400 includes an external device interface 414. The external device interface 414 may comprise a digital interface connector 416, an analog interface connector 418, and a communication device 420, which one or more of these items may be coupled to the microprocessor 410. The digital interface connector 416 may be configured to output the digital voltages V_{D1} to V_{DN} from the output of the A/D converter 406. The analog interface connector 418 may be configured to output the analog voltages V_{A1} to V_{AN} from the outputs of the transimpedance amplifiers 404-1 to 404-N, respectively. The microprocessor 410 may be adapted to enable and disable the outputting of the corresponding signals by the digital and analog interface connectors 416 and 418.

The communication device 420 provides a data interface between the microprocessor 410 and one or more external devices. For example, via the communication device 420, the microprocessor 410 may output information related to the power level of the electromagnetic signal irradiating the photodetector 402, the corresponding currents I₁(λ₁) to I_{N}(λ_{N}) generated by the photodetector 402, the digital voltages V_{D1} to V_{DN}, and other relevant information. Note that the microprocessor 410 may determine the currents I₁(λ₁) to I_{N}(λ_{N}) generated by the photodetector 402 by dividing the voltages V_{D1} to V_{DN} by the gains Z₁ to Z_{N}, respectively. Similarly, via the communication device 420, the microprocessor 410 may receive software updates, commands, measurement parameters, and other information from one or more external devices.

The photodetector system 400 also comprises a power supply 422 for supplying bias voltages to the various components of the system. In this example, for instance, the power supply 422 generates; (1) a bias voltage V_{B1} for the multi-junction photodetector 402; (2) a bias voltage V_{B2} for the transimpedance amplifiers 404-1 to 404-N; (3) a bias voltage V_{B3} for the A/D converter 406; (4) a bias voltage V_{B4} for the multiplexer 408; (4) a bias voltage V_{B5} for the memory 412; (5) a bias voltage V_{B6} for the microprocessor 410; and (4) a bias voltage V_{B7} for the external device interface 414. Although these voltages are represented with different variables, it shall be understood that one or more of these may be the same voltages.

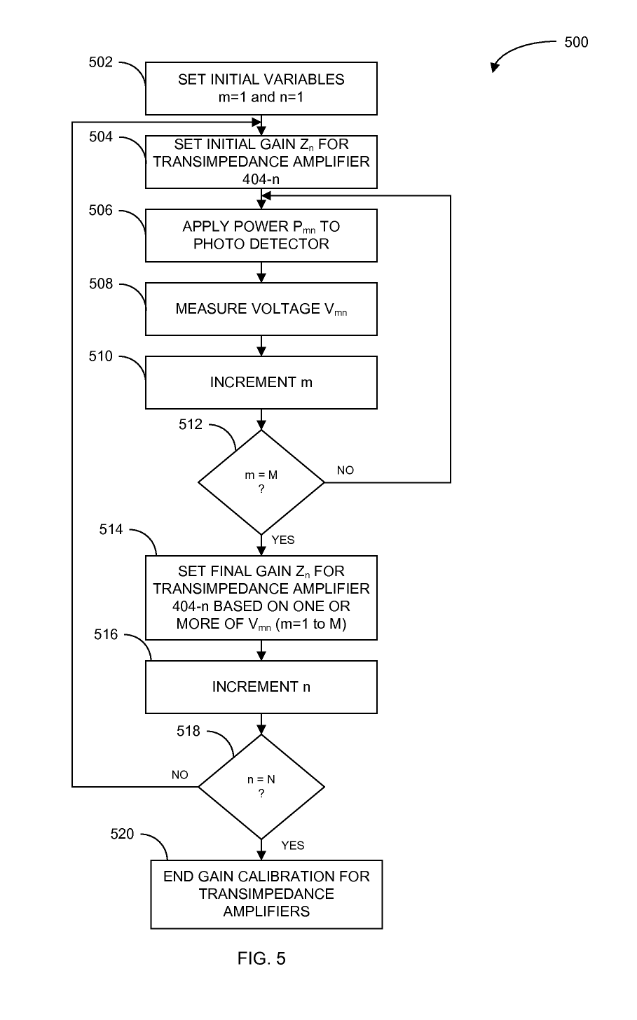

FIG. 5 illustrates a flow diagram of an exemplary method 500 of calibrating respective gains Z₁ to Z_{N} of transimpedance amplifiers 404-1 to 404-N associated with an exemplary microprocessor-based, multi-junction photodetector system 400 in accordance with another aspect of the disclosure. The gains Z₁ to Z_{N} may be calibrated, for example, to improve sensitivity at low power levels of the input signal, and to prevent or minimize compression of the transimpedance amplifiers 404-1 to 404-N at high power levels of the input signal. Although a particular method 500 for calibrating the gains Z₁ to Z_{N} is being described herein, it shall be understood that the gains may be calibrated in other manners. In this example, at least a portion of the operations described may be performed by the microprocessor 410 and/or with the assistance of one or more external devices.

According to the method 500, the microprocessor 410 sets initial variables m and n to one (1) (block 502). In this example, variable n represents the particular transimpedance amplifier 404-n whose gain is being calibrated, and m represents the number of different power levels at wavelength n (λₙ) of a test input signal applied to the photodetector 402. Then, the microprocessor 410 sets an initial gain Zₙ for the current transimpedance amplifier 404-n being calibrated (block 504). Then, a test input signal with a power level of Pₘₙ and wavelength λₙ is applied to the photodetector 402 (block 506). The microprocessor 410 then measures and stores the digital voltage Vₘₙ corresponding to the power level Pₘₙ (block 508). The microprocessor 410 then increments the variable m (block 510).

In block 512, the microprocessor 410 determines whether the variable m is equal to M, the number of different power levels of the test input signal at wavelength n to be used for calibrating the gain Zₙ of the current transimpedance amplifier 404-n. If m does not equal to M, which means that there are still one or more power levels remaining for calibrating the gain Zₙ of the current transimpedance amplifier 404-n, the operations of blocks 506 to 512 are repeated the next power level. On the other hand, if m is equal to M, which means that all input signal power levels for calibrating the current transimpedance amplifier 404-n have been used, the microprocessor 410 sets the final or calibrated gain Zₙ for the current transimpedance amplifier 404-n based on one or more of the measured voltages Vₘₙ for m=1 to M (block 514).

In block 516, the microprocessor 410 then increments the variable n in order to run the same calibration on the next transimpedance amplifier 404-n. In block 518, the microprocessor 410 determines whether the variable n is equal to N, the number of transimpedance amplifiers 404-1 to 404-N to be calibrated. If n does not equal to N, which means that there are still one or more transimpedance amplifiers to be calibrated, the operations of blocks 504 to 518 are repeated for the next transimpedance amplifier. On the other hand, if n is equal to N, which means that all the transimpedance amplifiers have already been calibrated, the microprocessor 410 may end the gain calibration of the transimpedance amplifiers (block 520).

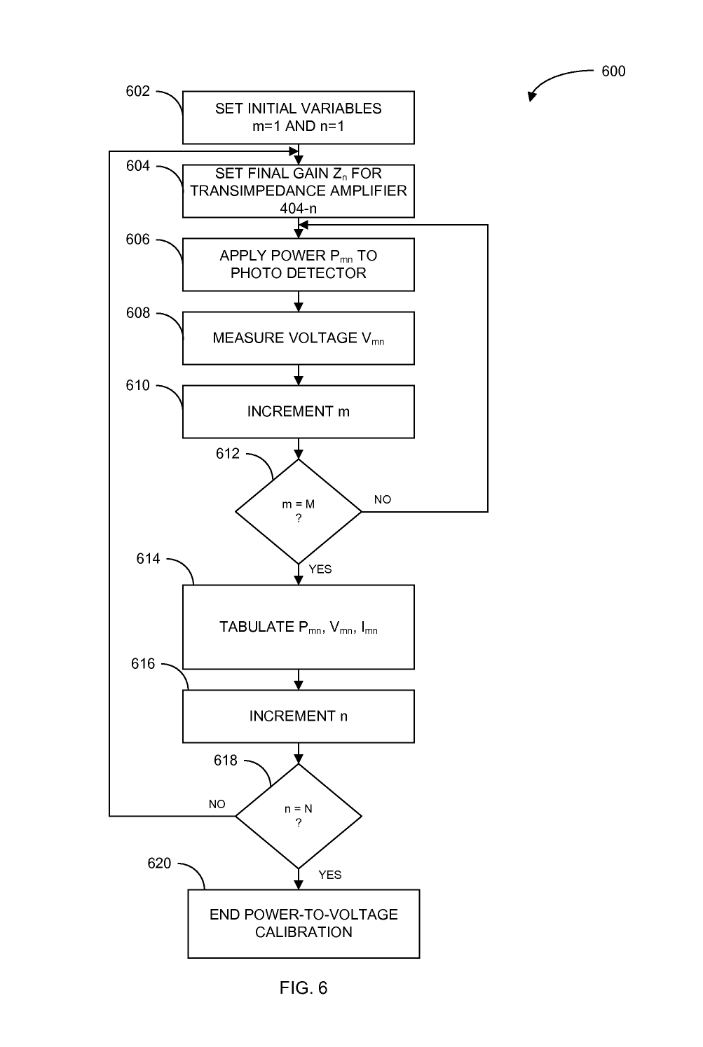

FIG. 6 illustrates a flow diagram of an exemplary method 600 for determining or calibrating a power-to-voltage response associated with an exemplary microprocessor-based, multi-junction photodetector system 400 in accordance with another aspect of the disclosure. This method 600 in essence calibrates the photodetector system 400 so that it is able to generate a measurement of the power level of an input signal within a defined tolerance. Although a particular method 600 for calibrating the photodetector system 400 is being described herein, it shall be understood that the calibration may proceed in other manners. In this example, at least a portion of the operations described may be performed by the microprocessor 410 and/or with the assistance of one or more external devices.

According to the method 600, the microprocessor 410 sets initial variables m and n to one (1) (block 602). Similar to the previous method, variable n represents the frequency band or wavelength λₙ for which the photodetector system 400 is being calibrated. The variable m represents the number of different power levels at wavelength n (λₙ) of a test input signal for which the photodetector system 400 is being calibrated. Then, the microprocessor 410 sets the final or calibrated gain Zₙ for the transimpedance amplifier 404-n associated with the wavelength n for which the photodetector system 400 is being calibrated (block 604). Then, a test input signal with a power level of Pₘₙ and wavelength λₙ is applied to the photodetector 402 (block 606). The microprocessor 410 then measures and stores the digital voltage Vₘₙ corresponding to the power level Pₘₙ (block 608). The microprocessor 410 then increments the variable m (block 610).

In block 612, the microprocessor 410 determines whether the variable m is equal to M, the number of different power levels of the test input signal at wavelength n to be used for calibrating the photodetector system 400. If m does not equal to M, which means that there are still one or more power levels remaining for calibrating the photodetector system 400 at the current wavelength n, the operations of blocks 606 to 612 are repeated the next power level. On the other hand, if m is equal to M, which means that all input signal power levels for calibrating the photodetector system 400 at the current wavelength n have been used, the microprocessor 410 tabulates the corresponding power level Pₘₙ, digital voltage Vₘₙ, and photodetector current Iₘₙ (block 614). When the table is completed for all wavelengths N and power levels M, the microprocessor 410 is able to provide an indication of the power level of an input signal during normal operations of the photodetector system 400.

An immediate application of device is measuring the input current at a constant output voltage. In this case, the microprocessor will adjust the gain for each amplifier to get a constant voltage output. By knowing the resistance associated with different gain stages, the input current can be determined very precisely.

In block 616, the microprocessor 410 then increments the variable n in order to run the same calibration of the photodetector system 400 for the next wavelength n. In block 618, the microprocessor 410 determines whether the variable n is equal to N, the number of wavelengths for which the photodetector system 400 is to be calibrated. If n does not equal to N, which means that there are still one or more remaining wavelengths for calibrating the photodetector system 400, the operations of blocks 604 to 618 are repeated for the next wavelength. On the other hand, if n is equal to N, which means that the photodetector system 400 has been calibrated for all the wavelengths, the microprocessor 410 may end the calibration of the photodetector system 400 (block 620).

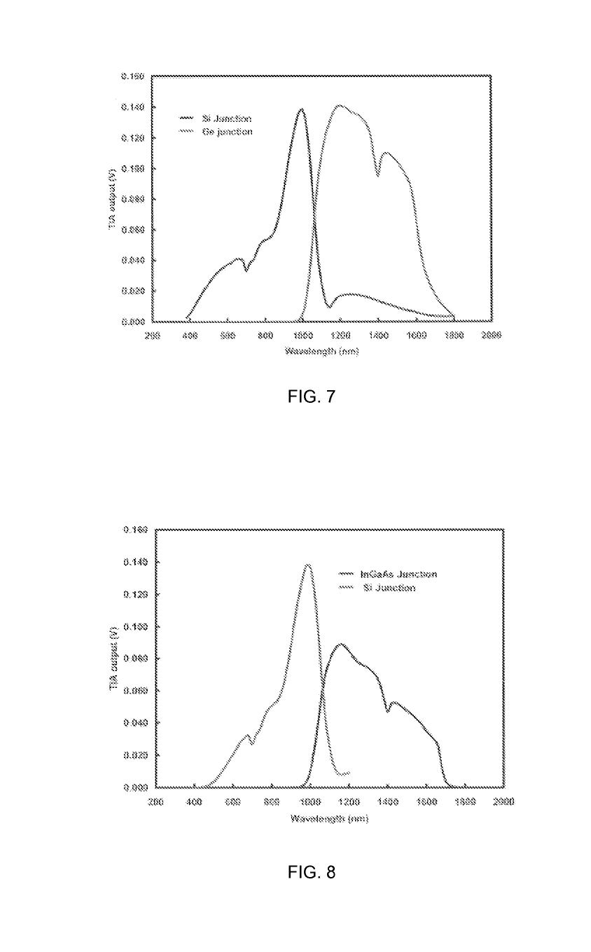

FIGS. 7 and 8 show graphically the test results of the performance of a photodetector system as described herein when illuminated with a Quartz halogen lamp. In particular, FIG. 7 illustrates the wavelength or frequency response for a Silicon and Germanium multi-junction photodetector. As noted, the Silicon-junction portion of the photodetector provides improved responsivity at relatively lower wavelengths (e.g., around 980 nanometers (nm)), whereas the Germanium-junction portion of the photodetector provides improved responsivity at relatively higher wavelengths (e.g., around 1200 nm).

Similarly, FIG. 8 illustrates the wavelength or frequency response for a Silicon and Indium Gallium-Arsenide multi-junction photodetector. As previously discussed, the Silicon-junction portion of the photodetector provides improved responsivity at relatively lower wavelengths (e.g., around 980 nm), whereas the Indium Gallium-Arsenide-junction portion of the photodetector provides improved responsivity at relatively higher wavelengths (e.g., around 1180 nm). Based on the distinct materials used for the multi-junction photodetector, a desired broadband response for the photodetector may be achieved.

While the invention has been described in connection with various embodiments, it will be understood that the invention is capable of further modifications. This application is intended to cover any variations, uses or adaptation of the invention following, in general, the principles of the invention, and including such departures from the present disclosure as come within the known and customary practice within the art to which the invention pertains.

1. A photodetector system, comprising:
a housing having at least one aperture formed therein;
at least one multi-junction photodetector device positioned within the housing, the photodetector having a first junction configured to generate a first photocurrent when irradiated with optical radiation within a first spectral range and having at least a second junction configured to generate a second photocurrent when irradiated with optical radiation within at least a second spectral range;
a first transimpedence amplifier and at least a second transimpedence amplifier positioned within the housing and in communication with the photodetector;
at least one analog to digital converter positioned within the housing and in communication with the first and second transimpedence amplifiers;
at least one microprocessor positioned within the housing and in communication with the analog to digital converter;
at least one memory device in communication with the microprocessor; and
at least one device interface positioned within the housing and in communication with the microprocessor.

2. The photodetector system of claim 1, wherein the device interface comprises a communication device.

3. The photodetector system of claim 1, wherein the device interface comprises a wireless communication device.

4. A photodetector system, comprising:
a multi-junction photodetector device comprising:
a first junction configured to generate a first current when irradiated with a first optical radiation component within a first spectral range; and
at least a second junction configured to generate a second current when irradiated with a second optical radiation component within a second spectral range that is different than the first spectral range; and
a microprocessor adapted to:
generate a first indication related to a first characteristic of the first optical radiation component based on the first current; and
generate a second indication related to a second characteristic of the second optical radiation component based on the second current.

5. The photodetector system of claim 4, wherein the first characteristic of the first optical radiation component comprises a first power level of the first optical radiation component.

6. The photodetector system of claim 5, wherein the second characteristic of the second optical radiation component comprises a second power level of the second optical radiation component.

7. The photodetector system of claim 4, further comprising:
a first device adapted to generate a first analog voltage based on the first current; and
at least a second device adapted to generate a second analog voltage based on the second current.

8. The photodetector system of claim 7, wherein the microprocessor is adapted to control a first gain of the first device, and control a second gain of the second device.

9. The photodetector system of claim 8, wherein the microprocessor is adapted to control the first gain of the first device in order to minimize compression of the first device at a first defined high power level of the first optical radiation component, and control the second gain of the second device in order to minimize compression of the second device at a second defined high power level of the second optical radiation component.

10. The photodetector system of claim 8, wherein the microprocessor is adapted to control the first gain of the first device in order to achieve a first defined sensitivity for the first device at a first defined low power level of the first optical radiation component, and control the second gain of the second device in order to achieve a second defined sensitivity for the second device at a second defined low power level of the second optical radiation component.

11. The photodetector system of claim 7, further comprising an analog-to-digital converter adapted to convert the first analog voltage into a first digital voltage, and convert the second analog voltage into a second digital voltage.

12. The photodetector system of claim 11, further comprising a multiplexer adapted to multiplex the first and second digital voltages onto an output, wherein the microprocessor is adapted to receive the first and second digital voltages from the output of the multiplexer.

13. The photodetector system of claim 4, further comprising a communication device adapted to facilitate communication of information between the microprocessor and one or more external devices.

14. The photodetector system of claim 13, wherein the microprocessor is adapted to provide data related to the first and second indications to the one or more external devices by way of the communication device.

15. The photodetector system of claim 7, further comprising an analog interface connector adapted to output the first and second analog voltages for transmission to one or more external devices.

16. The photodetector system of claim 15, wherein the microprocessor is adapted to enable or disable the outputting of the first and second analog voltages via the analog interface connector.

17. The photodetector system of claim 11, further comprising a digital interface connector adapted to output the first and second digital voltages for transmission to one or more external devices.

18. The photodetector system of claim 17, wherein the microprocessor is adapted to enable or disable the outputting of the first and second digital voltages via the digital interface connector.

19. The photodetector system of claim 4, further comprising a memory including one or more software modules readable and executable by the microprocessor, wherein the memory further comprises data related to the first and second indications.

20. The photodetector system of claim 4, further comprising a power supply adapted to supply a first bias voltage to the multi-junction photodetector device, and a second bias voltage to the microprocessor.

21. A photodetector system, comprising:
a multi-junction photodetector device comprising:
a first junction configured to generate a first current when irradiated with a first optical radiation component within a first spectral range; and
a second junction configured to generate a second current when irradiated with a second optical radiation component within a second spectral range that is different than the first spectral range; and
a circuit adapted to:
generate a first indication related to a first characteristic of the first optical radiation component based on the first current; and
generate a second indication related to a second characteristic of the second optical radiation component based on the second current.
